(19) United States
(12) Patent Application Publication
(10) Pub. No.: US 2026/0338883 A1
(43) Pub. Date: Oct. 29, 2026

(54) METHOD AND APPARATUS FOR SENSING OUT-OF-PLANE MAGNETIC FIELDS

(71) Applicant: Infineon Technologies AG, Neubiberg (DE)

(72) Inventors: Simon MENDISCH, Eichenau (DE); Klemens PRÜGL, Regensburg (DE); Bernhard ENDRES, Nabburg (DE); Wolfgang RABERG, Sauerlach (DE); Dieter SUESS, Herzogenburg (AT)

(21) Appl. No.: 19/655,117

(22) Filed: Apr. 22, 2026

(30) Foreign Application Priority Data
Apr. 29, 2025 (DE) 102025116414.2

(51) Int. Cl. G01R 33/09

(52) U.S. Cl. CPC G01R 33/098

(57) ABSTRACT

A magnetoresistive sensor is provided for magnetic field sensing. The sensor includes a layer stack including a reference system with a fixed magnetization and a synthetic antiferromagnetic (SAF) free-layer disposed adjacent to the reference system. The SAF free-layer includes a first ferromagnetic layer and a second ferromagnetic layer, each having a magnetic anisotropy oriented orthogonally to the magnetization direction of the reference system, and a non-magnetic coupling layer interposed between the first and second ferromagnetic layers. The coupling layer is configured to couple the ferromagnetic layers antiferromagnetically via a Ruderman-Kittel-Kasuya-Yosida (RKKY) interaction. Depending on the configuration, the sensor is sensitive to either out-of-plane or in-plane magnetic field components while exhibiting low cross-field sensitivity. The SAF structure enables low-noise operation with a near-zero net magnetization under zero field, supporting high linearity and directional robustness.

### CROSS-REFERENCE TO RELATED APPLICATION

This application claims priority to Germany Patent Application No. 102025116414.2, filed Apr. 29, 2025, the contents of which are incorporated herein by reference in their entireties.

### BACKGROUND

Magnetoresistive sensors, especially those based on the tunneling magnetoresistance (TMR) effect, may be used for measurement of external magnetic fields. To achieve a linear response to out-of-plane magnetic fields, ferromagnetic sensing layers with an in-plane magnetic easy axis may be employed. However, magnetization direction in such layers is directly influenced by the vector sum of out-of-plane and in-plane field components, resulting in significant cross-field sensitivity. This sensitivity can adversely affect the measurement accuracy, particularly when weak target signals must be detected in the presence of strong in-plane disturbances.

To reduce this susceptibility, vortex magnetization states have been explored. Vortex configurations may offer a certain degree of inherent immunity to in-plane fields by deflecting the vortex core rather than altering the sensitive out-of-plane magnetization component. However, this state may become unstable under stronger in-plane fields, eventually collapsing into a homogeneous magnetization state that reintroduces cross-field sensitivity. Therefore, both conventional and vortex-based approaches may present limitations in terms of field robustness and operational stability.

There may thus be a need to improve magnetoresistive sensor structures for out-of-plane magnetic field detection, in particular by reducing sensitivity to interfering in-plane magnetic fields. A goal may be to enhance the robustness and accuracy of a sensor response in realistic environments, while maintaining compatibility with compact integration and established thin-film processing technologies.

### SUMMARY

This need is addressed by the independent claims. Further embodiments are addressed by the dependent claims.

According to a first aspect, the present disclosure relates to a magnetoresistive sensor for sensing out-of-plane magnetic fields. The sensor includes a layer stack, which includes a reference system that exhibits an out-of-plane magnetization. Adjacent to this reference system, the sensor includes a synthetic antiferromagnetic (SAF) free-layer. The SAF free-layer includes a first ferromagnetic layer having an easy-plane anisotropy, a second ferromagnetic layer also having an easy-plane anisotropy, and a non-magnetic coupling layer positioned between the first and second ferromagnetic layers. Easy-plane anisotropy can arise from shape anisotropy due to dipolar interaction. This anisotropy might be tuned by an additional crystalline out-of-plane or easy-plane anisotropy. The non-magnetic coupling layer is configured to couple the two ferromagnetic layers antiferromagnetically via Ruderman-Kittel-Kasuya-Yosida (RKKY) interaction.

This defines a basic architecture of a magnetoresistive sensor according to the present disclosure. It specifies that the sensor is intended to measure magnetic fields oriented perpendicularly to the plane of the sensor layers (out-of-plane). The sensing element is formed by a multilayer structure. The reference system maintains a fixed out-of-plane magnetization, serving as a benchmark for detecting changes in the magnetization of the sensing layer. Adjacent to this reference, the sensor includes a SAF free-layer including two ferromagnetic layers with a preferred magnetization direction within the plane of the layer (easy-plane anisotropy). These two ferromagnetic layers are separated by a thin non-magnetic coupling layer, which is designed to induce antiferromagnetic interaction between them via the RKKY mechanism. As a result of this coupling, the two magnetic layers tend to align their magnetizations in opposite directions within the plane.

This sensor design may provide a stable and low-noise platform for measuring magnetic fields perpendicular to the sensor plane. By using a SAF as the free-layer, the structure may be inherently less sensitive to in-plane magnetic fields, as the antiparallel alignment of the magnetic layers tends to cancel out in-plane magnetic disturbances. The RKKY coupling may ensure strong and predictable antiferromagnetic alignment, improving thermal stability and magnetic stiffness of the sensing layer. Furthermore, the easy-plane anisotropy may promote stable in-plane magnetization when no field is applied, which may make the out-of-plane response more predictable and enable a near-linear signal characteristic. Overall, the structure may support high precision and reliability in environments where external magnetic noise, especially from in-plane directions, could otherwise degrade performance.

In some embodiments, a magnetic anisotropy and magnetic moments of the first and second ferromagnetic layers are configured to cause a net magnetization of the SAF free-layer to lie in-plane for any external magnetic field that is purely in-plane. When an external out-of-plane field Hz is applied, the two antiferromagnetically coupled magnetizations may tilt coherently away from the plane, producing a net out-of-plane component that rises approximately linearly with Hz up to a characteristic field Hsat. Above this level the SAF may approach a saturated state with both moments parallel to Hz. Because the in-plane torque produced by Hz is balanced by the strong antiparallel coupling, the free-layer may remain insensitive to parasitic in-plane fields, while providing a predictable, near-linear response to a desired out-of-plane component.

In some embodiments, the non-magnetic coupling layer is composed of ruthenium, iridium, tantalum, tungsten, or combinations of these materials. This may define the material composition of the non-magnetic coupling layer that is positioned between the two ferromagnetic layers of the SAF free-layer. The purpose of this layer is to mediate an antiferromagnetic interaction between the adjacent ferromagnetic layers. The specified materials—ruthenium, iridium, tantalum, and tungsten—are known to support RKKY-type coupling, which enables such antiferromagnetic alignment at nanometer or sub-nanometer spacer thicknesses. The selection of these particular elements may be based on their effectiveness in establishing stable and controllable coupling behavior in magnetic multilayer systems. The use of these materials for the non-magnetic coupling layer may allow precise control over the strength and nature of the interlayer exchange interaction, which is essential for maintaining the antiferromagnetic alignment within the SAF structure. In particular, ruthenium and iridium may be used in high-performance magnetic tunnel junctions due to their ability to induce strong and stable antiparallel alignment over ultrathin separations. This stability may enhance the magnetic reliability of the sensing layer under varying thermal and magnetic conditions. Additionally, the flexibility to choose among or combine different coupling materials may enable process integration across different fabrication platforms and facilitate material tuning to match specific sensor performance targets, such as desired coupling strength, thermal tolerance, or deposition compatibility.

In some embodiments, the first ferromagnetic layer of the synthetic antiferromagnetic free-layer includes a cobalt-iron-boron (CoFeB) and/or cobalt-iron (CoFe) alloy. This may specify the material composition of the first ferromagnetic layer in the SAF free-layer. It indicates that the layer is made from, or at least includes, a CoFeB or CoFe alloy. These materials are commonly used in magnetoresistive devices, particularly in magnetic tunnel junctions, due to their favorable combination of soft magnetic properties and high spin polarization. The first ferromagnetic layer, being adjacent to a tunnel barrier, may function as the signal-generating layer in the sensor by responding to external magnetic fields and modulating the resistance of the device through the tunnel magnetoresistance effect. The use of CoFeB or CoFe alloys in the first ferromagnetic layer may provide several benefits. These materials are known for their high magnetoresistance ratio when used in conjunction with MgO tunnel barriers, which can lead to improved signal amplitude and sensitivity in TMR sensors. They also exhibit low coercivity and good soft-magnetic behavior, allowing for dynamic and reversible response to external magnetic fields. Additionally, CoFeB, in particular, is amorphous as-deposited and crystallizes during annealing in a way that promotes excellent interface quality and magnetic uniformity, which may contribute to enhanced device reproducibility and reliability. Overall, the choice of these alloys may enable robust and efficient magnetoresistive sensing, particularly in demanding field environments or miniaturized device formats.

In some embodiments, the first ferromagnetic layer includes at least one additional element selected from the group consisting of iron (Fe), cobalt (Co), platinum (Pt), palladium (Pd), or nickel (Ni), wherein the additional element is deposited on the CoFeB or CoFe alloy in order to modify the magnetocrystalline anisotropy and to enable RKKY coupling. This may add to the composition of the first ferromagnetic layer by introducing optional elements—namely Fe, Co, Pt, Pd, or Ni—that may be used as an overlayer or dopant in addition to the base CoFeB or CoFe alloy. These elements are known to influence key magnetic properties such as magnetocrystalline anisotropy, which governs the preferred direction of the magnetic moments in the material. The addition of these elements may also help in achieving or strengthening the RKKY-mediated antiferromagnetic coupling between the first and second ferromagnetic layers by tailoring interfacial properties or magnetic moment balance. This tuning may be needed for achieving the desired magnetic response and coupling efficiency in the SAF configuration. By incorporating additional magnetic or noble metal elements into the first ferromagnetic layer, the anisotropy and magnetic moment of the signal layer may be finely adjusted to meet application-specific performance targets. For example, platinum and palladium are known to enhance perpendicular magnetic anisotropy at interfaces, which may be beneficial for sensors requiring precise out-of-plane responses. Nickel-iron alloys can be used to reduce the coercive field Hc and thereby provide a soft-magnetic response, improving the ease of coherent rotation under the target out-of-plane field. Furthermore, the inclusion of these elements may optimize the coupling conditions at the interface with the non-magnetic spacer, thereby supporting stronger and more stable RKKY interactions. Altogether, this material flexibility may improve the linearity, sensitivity, and cross-field robustness of the sensor, while also allowing for enhanced process compatibility and reproducibility during thin-film deposition.

In some embodiments, the magnetoresistive sensor further includes a tunnel barrier that is interposed between the synthetic antiferromagnetic free-layer and the reference system. This specifies that the magnetoresistive sensor may include a tunnel barrier positioned between the SAF free-layer and the reference system. The tunnel barrier is a thin, non-conductive layer—typically made of materials such as magnesium oxide—that allows quantum mechanical tunneling of electrons between the adjacent magnetic layers. This tunneling current depends sensitively on the relative orientation of the magnetizations in the free-layer and the reference layer, giving rise to the tunnel magnetoresistance (TMR) effect, which is the core sensing principle in many high-performance magnetic sensors. The inclusion of a tunnel barrier may enable the sensor to operate based on the TMR effect, which may offer higher signal amplitudes and sensitivity compared to other magnetoresistive effects, such as the giant magnetoresistance (GMR). The barrier allows for spin-dependent tunneling, which can result in a significant resistance change when the magnetizations of the free and reference layers switch between parallel and antiparallel configurations. This may lead to improved signal-to-noise ratio (SNR) and higher precision in magnetic field detection. Furthermore, the use of a tunnel barrier can support scaling to very small sensor geometries while preserving high output levels, which may be advantageous for integration into densely packed or miniaturized electronic systems.

In some embodiments, the tunnel barrier is interposed specifically between the first ferromagnetic layer and the reference system. The tunnel barrier may be placed between the first ferromagnetic layer of the synthetic antiferromagnetic free-layer—typically acting as the signal layer—and the reference system. This means that the tunneling current, and thus the magnetoresistive signal, is directly influenced by the relative magnetization alignment between the reference system and the first ferromagnetic layer, which is positioned closest to the tunnel barrier. Positioning the tunnel barrier between the first ferromagnetic layer and the reference system may provide a well-defined and predictable tunneling interface, which is essential for achieving high TMR performance. This configuration may allow the magnetization of the first ferromagnetic layer, which is responsive to external out-of-plane magnetic fields, to directly modulate the tunneling current. The resulting signal may be highly sensitive and directionally selective, as it is primarily governed by the orientation of the signal layer relative to the fixed reference. Additionally, placing the tunnel barrier adjacent to the more carefully engineered signal layer—often optimized for specific anisotropy and spin polarization characteristics—may enhance the reproducibility, symmetry, and linearity of the sensor response across multiple operating conditions. This structure may also simplify the layer stack architecture and facilitate standard TMR fabrication processes.

In some embodiments, the magnetoresistive sensor further includes a conductive spacer layer that is interposed between the synthetic antiferromagnetic free-layer and the reference system. This provides an alternative to the tunnel barrier configuration. Instead of a tunnel barrier, a conductive spacer layer is used to separate the synthetic antiferromagnetic free-layer from the reference system. In this configuration, the sensor may operate based on the giant magnetoresistance (GMR) effect rather than the tunnel magnetoresistance (TMR) effect. In a GMR-based device, electron transport occurs through the conductive spacer via diffusive conduction, and the resistance of the device depends on spin-dependent scattering at the interfaces and within the magnetic layers themselves. The use of a conductive spacer layer instead of a tunnel barrier may provide certain advantages in terms of fabrication complexity and process compatibility. GMR structures generally do not require the precise control of insulating layer thickness as for TMR barriers, which may simplify manufacturing and improve yield. Additionally, conductive spacer layers may offer lower overall resistance and better thermal stability, which can be beneficial in high-current or high-temperature applications. This configuration may also be more tolerant of process variations, especially in applications where absolute sensitivity is less critical than robustness or integration with other circuit elements. Furthermore, the option to use either a tunnel barrier or a conductive spacer may provide design flexibility, allowing the sensor architecture to be tailored to different system requirements or constraints.

In some embodiments, the second ferromagnetic layer includes a multilayer stack that includes one or more layers selected from the group consisting of CoFe, CoNi, NiFe, CoB, CoFeB, or FeB, wherein the multilayer stack is configured to balance the magnetic moment of the first ferromagnetic layer. This focuses on the structure and function of the second ferromagnetic layer within the SAF free-layer. It specifies that this second layer may be composed of multiple sub-layers—forming a multilayer stack—that can include materials such as cobalt-iron (CoFe), cobalt-nickel (CoNi), nickel-iron (NiFe), cobalt-boron (CoB), cobalt-iron-boron (CoFeB), or iron-boron (FeB). These multilayers may also be used in some embodiments for the first ferromagnetic layer. The purpose of this multilayer configuration is to magnetically balance the first ferromagnetic layer, which lies adjacent to the tunnel barrier or conductive spacer and serves as the signal layer. The balancing effect pertains to both magnetic moment and anisotropy characteristics, ensuring that the overall SAF structure behaves as intended under external fields. The use of a multilayer stack in the second ferromagnetic layer may enable fine-grained control over the total magnetic moment, anisotropy, and dynamic behavior of the SAF free-layer. By carefully selecting and stacking materials with known magnetic properties, one may tailor the second layer to effectively counteract or complement the first layer, thereby achieving an optimized antiferromagnetic configuration. This balance may help to tune the linear range, stabilize the in-plane antiparallel alignment, enhance linearity in out-of-plane response, and suppress undesired cross-field sensitivity. Moreover, certain materials such as NiFe and CoFeB are known for their soft magnetic properties and ease of integration, while others like CoNi offer higher magnetic stiffness or anisotropy tuning. The multilayer structure may also provide better thickness control, thermal stability, and compatibility with deposition processes used in modern MR sensor fabrication, potentially improving yield, repeatability, and long-term performance.

In some embodiments, the synthetic antiferromagnetic free-layer has a total thickness that is less than 10 nanometers, less than 8 nanometers, or even less than 6 nanometers. This places a constraint on the total physical thickness of the SAF free-layer, which includes both ferromagnetic layers and the non-magnetic coupling layer between them. Specifically, the entire SAF structure may be limited to a thickness of less than 10 nanometers. This dimensional requirement encompasses all constituent layers and is indicative of a highly miniaturized magnetic sensor architecture. Limiting the SAF free-layer thickness to under 10 nanometers may provide several important benefits. First, the production time (e.g., by sputtering) may be reduced which in turn may reduce costs. Further, it may enable the fabrication of ultra-compact sensor structures that are suitable for high-density integration, such as in system-on-chip applications or tightly packed sensor arrays. Second, reducing the total magnetic volume may lower the energy required for coherent rotation, enabling faster and more energy-efficient switching. Third, thinner SAF structures may exhibit better control over coupling strength, particularly through the RKKY interaction, which is most effective over sub-nanometer to few-nanometer distances. Furthermore, a compact magnetic stack may improve the signal fidelity in TMR-based devices by reducing noise contributions and parasitic magnetic effects from thicker, more complex structures. Finally, maintaining such a thin profile may support process scalability and compatibility with standard back-end-of-line (BEOL) integration in semiconductor manufacturing.

In some embodiments, the first ferromagnetic layer of the synthetic antiferromagnetic free-layer has a thickness that lies between 1 nanometer and 2 nanometers. This defines a specific thickness range for the first ferromagnetic layer, which may function as the signal layer in the SAF free-layer stack. It may be manufactured with a thickness of at least 1 nanometer but not more than 2 nanometers. This narrow range may be useful for both magnetic performance and compatibility with adjacent layers, especially the tunnel barrier in a TMR configuration. By limiting the thickness of the first ferromagnetic layer to the range of 1 to 2 nanometers, the sensor design may achieve a well-balanced trade-off between magnetic signal strength, switching behavior, and coupling effectiveness. A layer thinner than 1 nanometer may suffer from discontinuities, degraded crystallinity, or suppressed magnetic moment, which could compromise device reliability and sensitivity. Conversely, a layer thicker than 2 nanometers may introduce excessive magnetic stiffness or undesirable stray fields, reduce the efficiency of RKKY coupling, or disturb the balance with the second ferromagnetic layer in the SAF stack. Staying within this range may also enhance the spin polarization of the tunneling electrons (in TMR structures), thereby maximizing the magnetoresistance ratio. Moreover, such thin layers are compatible with modern deposition techniques such as sputtering or atomic layer deposition (ALD), and may support the realization of low-power, high-speed magnetic sensors for demanding applications.

In some embodiments, the SAF free-layer is patterned into a circular or cylindrical geometry. This means that the layer is formed with either a circular or cylindrical geometry, meaning that the lateral cross-section of the layer (viewed from above) is round, and the vertical profile is uniform, forming a cylinder-like body. This geometric configuration can apply both to planar and three-dimensional patterning processes during device fabrication. Patterning the SAF free-layer into a circular or cylindrical shape may help to suppress or eliminate unwanted shape anisotropy effects. Shape anisotropy arises due to the geometric distribution of magnetic material and can create directional preferences in magnetization, which may interfere with controlled switching behavior or introduce nonlinearities in the sensor response. A circular geometry provides rotational symmetry, meaning there is no preferred in-plane direction for magnetization, which may allow the SAF to maintain a more uniform magnetic state. This may be particularly beneficial in sensors that must distinguish magnetic fields in the out-of-plane direction without distortion or bias caused by lateral geometry. Additionally, cylindrical structures are well-suited for use in simulations, modeling, and process control, and they may help optimize edge stability and reduce the risk of vortex nucleation or domain wall formation at boundaries. Overall, this shape may contribute to more predictable, stable, and linear sensor performance.

In some embodiments, the diameter of the circular or cylindrical SAF free-layer is less than one micrometer. This introduces a dimensional constraint on the SAF free-layer, specifically concerning its lateral size. It requires that the diameter of the circular or cylindrical SAF structure be smaller than one micrometer (1 μm). This constraint may apply regardless of the overall sensor layout and may be particularly relevant to the scaling and integration of the sensing element into compact device architectures.

In some embodiments, the reference system includes a stack exhibiting perpendicular magnetic anisotropy. The stack may include one or more layers selected from the group consisting of cobalt/platinum (Co/Pt), nickel/platinum (Ni/Pt), cobalt/nickel (Co/Ni), gadolinium-cobalt (GdCo), cobalt-chromium-platinum (CoCrPt), iron-platinum (FePt), or rare-earth-based alloys. This defines the structure and material composition of the reference system used in the magnetoresistive sensor. The reference system serves as the magnetically fixed layer against which changes in the free-layer's magnetization are compared to generate the sensor signal. The reference system may be designed as a multilayer stack that exhibits perpendicular magnetic anisotropy (PMA), meaning the magnetization naturally aligns out of the film plane. Employing a stack with PMA in the reference system may provide a stable and well-defined out-of-plane magnetization axis, which is needed for accurate out-of-plane field sensing. PMA structures are less prone to reorientation under in-plane fields, which may enhance signal stability and directional selectivity. The listed material systems combine high magnetic anisotropy with excellent thermal stability and resistance to external field disturbances. These materials may also support high spin polarization and good interfacial quality, which can contribute to maximizing the magnetoresistive signal, particularly in TMR-based designs. The inclusion of rare-earth-based alloys may offer extended temperature range performance and tailored magnetic properties. Overall, such a PMA reference stack may enhance the sensor's robustness, linearity, and sensitivity while ensuring consistent performance under varying operating conditions.

In some embodiments, the reference layer is magnetically pinned by exchange-coupling it to an antiferromagnetic pinning layer. The pinning layer may include one or more antiferromagnetic materials selected from the group consisting of iridium-manganese (IrMn), platinum-manganese (PtMn), iron-manganese (FeMn), nickel-manganese (NiMn), nickel-oxide (NiO), chromium-oxide (Cr₂O₃), or combinations thereof. The antiferromagnetic pinning layer may be arranged adjacent to the reference layer—optionally separated by a thin dusting or seed layer—to establish an exchange-bias field that fixes the magnetization direction of the reference layer along the perpendicular anisotropy axis. Coupling the reference layer to such a pinning layer may improve thermal robustness, suppresses spontaneous reversal under external in-plane or oblique fields, and may ensure a well-defined comparison axis for the synthetic-antiferromagnetic free-layer. Exchange-bias stabilization may further enhance sensor linearity and minimize offset drift, thereby supporting reliable out-of-plane field detection over an extended temperature and field range.

In some embodiments, the layer stack of the magnetoresistive sensor includes precisely one reference system. This limits the sensor configuration to include a single reference system within the magnetic layer stack. That is, only one magnetic element in the stack is fixed in its magnetization direction and serves as the reference for detecting changes in the magnetization of the adjacent synthetic antiferromagnetic (SAF) free-layer. No additional reference systems are present within the same layer stack. Utilizing only one reference system may reduce structural and fabrication complexity while still enabling accurate and reliable field sensing. This configuration may be especially beneficial in applications where space, energy consumption, or cost constraints are significant. By eliminating the need for a second reference layer, the sensor architecture may be simplified, potentially resulting in a thinner stack and improved manufacturability. Moreover, a single-reference design may reduce internal magnetic interactions that could otherwise introduce signal ambiguity or unwanted coupling effects. This may lead to a more stable and isolated response of the free-layer to external out-of-plane fields. Additionally, the absence of multiple competing reference axes may help maintain the desired directionality and linearity of the sensor output, which is especially relevant for one-dimensional or single-axis magnetic field detection.

In some embodiments, the magnetoresistive sensor further includes a signal processing circuit that is configured to measure variations in magnetoresistance resulting from rotation of the ferromagnetic layer at the tunnel barrier and to output a signal indicative of an out-of-plane magnetic field strength. This introduces a functional extension to the sensor by incorporating a signal processing circuit. The circuit is configured to detect changes in magnetoresistance that arise from the rotation of the magnetization vector in the ferromagnetic signal layer (e.g., the first ferromagnetic layer of the SAF free-layer) as it responds to an external out-of-plane magnetic field. These magnetization changes, in turn, alter the relative alignment between the free and reference layers and modulate the electrical resistance across the tunnel barrier. The circuit interprets these resistance changes and converts them into an output signal that reflects the magnitude of the external out-of-plane magnetic field. Integrating a signal processing circuit into the sensor design may enhance its usability and functionality. This integration may allow real-time conversion of raw resistance changes into calibrated output signals, enabling direct interfacing with microcontrollers, data acquisition systems, or digital logic. By measuring magnetoresistance variations at the tunnel barrier—where the signal layer interacts most sensitively with the reference system—the circuit may produce highly accurate and high-resolution magnetic field readings. The circuit may also implement linearization, filtering, temperature compensation, or offset correction, depending on the application. This internal signal conditioning may simplify external circuitry, reduce total system cost, and improve signal integrity, especially in electromagnetically noisy environments. Furthermore, having the output correlate directly with out-of-plane field strength may support precise and directional magnetic field sensing in industrial, automotive, or consumer applications.

In some embodiments, the magnetoresistive sensor further includes at least one soft magnetic shielding that is arranged adjacent to the layer stack and configured to reduce an influence of an external magnetic field along a shielding axis on the free-layer. This adds a passive field-shaping component to the sensor architecture in the form of a soft magnetic shielding element. The shielding is positioned close to the magnetic layer stack—specifically near the SAF free-layer—and is oriented such that it influences magnetic fields aligned along a particular direction, referred to here as the shielding axis. The function of this shielding is to reduce or suppress the effect of external magnetic fields along that axis before they reach and disturb the magnetization state of the free-layer. Incorporating soft magnetic shielding adjacent to the sensing stack may significantly enhance the robustness of the sensor by mitigating the impact of parasitic magnetic fields, particularly in-plane cross-fields that could otherwise distort the intended out-of-plane measurement. Soft magnetic materials such as permalloy (NiFe) are known for their high permeability, allowing them to attract and redirect magnetic flux lines. By strategically placing such a shield near the sensor, interfering field components may be deflected away from the sensitive region, thereby preserving the magnetic integrity and stability of the free-layer. This may improve measurement accuracy, reduce noise, and prevent saturation or hysteresis effects in the active sensing elements. Moreover, this approach can serve as a passive, energy-free mechanism to increase the signal-to-noise ratio and extend the linear operating range of the sensor, particularly in environments with strong or fluctuating magnetic interference. The concept also supports modular design strategies, where shielding performance can be tuned through the choice of material, geometry, and placement without altering the core sensor architecture.

In some embodiments, the shielding is designed to generate an opposing magnetic field in response to the external magnetic field. This characterizes the functional behavior of the soft magnetic shielding. It specifies that the shielding is not merely a passive physical barrier but is designed to actively respond to external magnetic fields by generating a magnetic field of its own that opposes the direction of the incoming field. This opposing field is induced within the shielding material as a result of its high magnetic permeability and interaction with the external magnetic flux. The effect is to counteract and partially cancel the field component that would otherwise act on the free-layer (and also on the reference layer) of the magnetoresistive sensor. Designing the shielding to generate an opposing field may provide a dynamic and self-regulating mechanism for mitigating the effects of unwanted magnetic interference. Unlike rigid or static shielding approaches, this leverages the intrinsic magnetic response of the shielding material to adaptively attenuate external fields. The opposing field may effectively neutralize or significantly reduce the net magnetic flux reaching the sensitive region of the sensor, particularly along the shielding axis. This may help preserve the magnetization state of the synthetic antiferromagnetic free-layer and reduce signal distortion caused by in-plane or oblique field components. In practical terms, such shielding may enable the sensor to operate reliably in more electromagnetically noisy environments, extend the operational range of the device, and maintain linearity and accuracy under conditions where strong or fluctuating fields are present. It may also reduce the need for software-based compensation or complex signal post-processing, thereby simplifying overall system design.

In some embodiments, the shielding is arranged laterally adjacent to the layer stack. This specifies the spatial arrangement of the shielding relative to the magnetic layer stack of the sensor. It states that the shielding may be positioned beside the stack in a lateral direction, meaning it may be placed along the same plane as the thin film layers, or above or below them. The shielding may therefore lie next to the synthetic antiferromagnetic free-layer and the reference system along the x- or y-axis, depending on the sensor layout. Positioning the shielding laterally adjacent to the sensor's active layer stack may provide targeted suppression of magnetic field components that propagate parallel to the plane of the sensor—commonly referred to as in-plane cross-fields. These in-plane fields may be particularly disruptive in magnetoresistive sensors that are designed to detect out-of-plane magnetic components, as they may unintentionally alter the magnetization of the free-layer and degrade the accuracy of the measurement. A lateral shielding arrangement may serve to intercept and redirect these parasitic fields before they reach the sensitive region, thereby maintaining a stable and linear sensor response. Furthermore, lateral shielding can be implemented without significantly increasing the sensor's vertical height, which may be advantageous for integration into planar chip designs and space-constrained applications. This configuration may also simplify the mechanical and process integration of the shield, allowing it to be patterned and deposited using standard lithographic or sputtering techniques alongside the rest of the sensor structure.

In some embodiments, the shielding is arranged above or below the layer stack. This describes an alternative or additional spatial arrangement of the magnetic shielding in the sensor. Specifically, it states that the shielding may be placed vertically relative to the sensor's magnetic layer stack—either positioned on top of or beneath the stack, along the direction perpendicular to the layer plane. Placing the shielding above or below the magnetic layer stack may provide enhanced protection against magnetic fields that are oriented perpendicular to the sensor plane or that exhibit complex three-dimensional field components. Such vertical shielding may be particularly effective in environments where magnetic interference originates from sources located in the out-of-plane direction—such as neighboring devices, power electronics, or rotating machinery. The top or bottom placement of shielding may also work synergistically with lateral shielding to form an enclosure or partial enclosure around the sensing region, thus creating a more comprehensive shielding profile. Additionally, this vertical configuration may allow greater freedom in tuning the effective shielding range by varying the vertical distance between the shield and the sensor or by stacking multiple shield layers. From a fabrication standpoint, top-side shielding can be deposited after sensor processing without affecting underlying layer quality, while bottom-side shielding can be integrated early in the process as part of the substrate or buffer layer design. This flexibility may support a wide variety of sensor packaging and system integration scenarios while maintaining signal stability and measurement accuracy.

In some embodiments, an extension of the shielding perpendicular to the shielding axis is greater than the extension of the shielding parallel to the shielding axis. The shielding may have an asymmetric shape in which its physical dimension measured perpendicular to the shielding axis is larger than the dimension measured parallel to that axis. The shielding axis refers to the direction along which the external magnetic field is to be suppressed. Thus, the geometry may intentionally be designed so that the shield presents a broader surface area in the direction orthogonal to the field it is meant to attenuate. Designing the shielding with a larger extension perpendicular to the shielding axis may improve its ability to redirect or neutralize external magnetic fields that would otherwise reach the sensitive regions of the sensor. This geometry may enhance the demagnetizing effect, allowing the shielding material to more effectively concentrate and redirect the magnetic flux lines away from the synthetic antiferromagnetic free-layer. As a result, the influence of interfering fields along the shielding axis may be substantially reduced. Moreover, this configuration can create a stronger opposing magnetic field across a larger area, improving field cancellation uniformity and expanding the protected zone around the sensor. From a design perspective, this anisotropic geometry can be tailored to match expected field distributions in specific applications, providing directional shielding without unnecessarily increasing material volume or sensor footprint. Ultimately, this may lead to improved signal integrity, lower cross-field sensitivity, and higher measurement accuracy, particularly in applications with strong directional magnetic noise.

In some embodiments, the shielding is cuboidal in shape. A cuboid is a three-dimensional rectangular solid with flat faces and right-angled corners, typically defined by three orthogonal linear dimensions (length, width, and height). In the context of the sensor design, this means the shielding element may be shaped like a block or brick, with straight, flat surfaces aligned along principal axes—likely corresponding to the orientation of the layer stack and sensor substrate. A cuboidal shielding shape may offer practical and functional benefits in magnetoresistive sensor design. Geometrically, cuboids are simple to fabricate using standard thin-film deposition and lithographic patterning techniques, which may enhance manufacturing precision and reproducibility. The straight edges and defined faces allow for predictable and uniform magnetic behavior, particularly in guiding and redirecting magnetic flux along desired paths. This regular shape may also support straightforward integration into chip-level packaging, enabling the shield to fit neatly alongside or above sensor components. From a functional standpoint, the planar faces of a cuboid may align well with field lines in controlled configurations, optimizing the effectiveness of magnetic redirection or cancellation. Moreover, cuboidal geometries can be easily scaled or stacked to tune the shielding strength or range, making them adaptable to different levels of field interference. Altogether, a cuboidal shield may provide a balance of simplicity, efficacy, and process compatibility, supporting stable and compact sensor architectures.

In some embodiments, the shielding includes a first soft-magnetic bar and a second soft-magnetic bar which intersect at a right angle. This describes a composite configuration of the shielding system in which at least two separate soft-magnetic bars are included. These bars are arranged to intersect each other orthogonally—e.g., at a 90-degree angle. This structural arrangement forms a cross-shaped or grid-like configuration that extends shielding capability across two perpendicular directions. The bars themselves may be composed of a soft magnetic material, such as NiFe or CoFe alloys, known for their high magnetic permeability and low coercivity. A shielding structure composed of two intersecting soft-magnetic bars may allow for effective suppression of magnetic fields in two orthogonal directions—typically corresponding to both in-plane axes (x and y) of the sensor. This cross-shaped configuration may therefore enhance the sensor's immunity to multidirectional in-plane magnetic interference, which may be a source of measurement error in applications involving rotating machinery, current-carrying conductors, or variable magnetic environments. By providing bidirectional shielding, the structure may maintain the magnetization stability of the synthetic antiferromagnetic free-layer more effectively than a single-bar configuration. Additionally, the right-angle arrangement may create overlapping magnetic field redirection zones, further increasing the uniformity and strength of the shielding effect across the sensor's active area. The design is also modular and scalable—additional orthogonal bars or layered grids can be added to tailor the shielding performance to specific use cases. Overall, this approach may result in more robust sensor operation under real-world conditions with complex and fluctuating magnetic field vectors.

In some embodiments, the shielding includes a plurality of soft magnetic bars arranged in parallel, wherein each of the bars has a longitudinal axis that extends either perpendicularly or parallel to the shielding axis. This describes a more complex and adaptable shielding arrangement in which multiple soft magnetic bars are included, rather than just one or two. These bars are aligned in parallel with one another, and their individual long axes (longitudinal axes) are oriented either parallel to or perpendicular to a defined shielding axis—that is, the axis along which the shielding is intended to mitigate external magnetic field effects. The orientation of the bars may be selected based on the dominant direction of interfering fields in the sensor's intended application environment. Arranging multiple soft magnetic bars in parallel may significantly enhance the shielding effectiveness by expanding the spatial coverage and magnetic flux handling capacity of the structure. When the longitudinal axes of the bars are aligned with or orthogonal to the shielding axis, the configuration can be tuned to either redirect or block specific components of external magnetic fields more effectively. For example, bars aligned perpendicular to the shielding axis may maximize magnetic flux deflection, while bars aligned parallel to it may help channel field lines and create a distributed opposing field. This structural flexibility may allow for targeted optimization of the shielding for specific operating conditions—such as protecting against dominant field noise in one direction or creating uniform protection in sensor arrays. Moreover, the use of multiple bars rather than a single monolithic shield can reduce eddy current formation and thermal loading, which may be beneficial in high-frequency or high-temperature environments. From a manufacturing perspective, parallel bar arrays can be implemented using patterned deposition and etching techniques, supporting high-throughput, scalable fabrication. Overall, this approach may lead to better control over cross-field interference and increased robustness of the sensor under complex magnetic loads.

In some embodiments, a system for magnetic field sensing is provided, wherein the system includes a magnetoresistive sensor according to any one of the preceding embodiments and a control unit that is configured to process output signals from the magnetoresistive sensor to determine the magnitude of an external out-of-plane magnetic field while compensating for in-plane cross-field effects. This extends the scope from a stand-alone sensor device to an integrated sensing system. The system includes a magnetoresistive sensor as described in the preceding embodiments, and additionally includes a control unit. The control unit is responsible for processing the output signals generated by the sensor and performing two key functions: (1) determining the magnitude of the magnetic field component oriented out-of-plane, and (2) compensating for the influence of in-plane magnetic field components that may otherwise distort or interfere with the measurement of the desired out-of-plane field. Integrating the magnetoresistive sensor with a control unit may enhance the functionality, accuracy, and adaptability of the overall sensing system. The control unit may implement algorithms or calibration routines that allow the system to isolate the out-of-plane magnetic signal from unwanted in-plane disturbances—often referred to as cross-field interference. This may be important in real-world environments where magnetic fields may vary unpredictably in multiple directions. By incorporating compensation techniques, such as mathematical correction, real-time feedback, or differential signal processing, the system may improve measurement fidelity and robustness. Additionally, the control unit may handle signal conditioning, filtering, linearization, and communication with external devices, enabling seamless integration into larger electronic platforms such as automotive control units, industrial controllers, or consumer electronics. This system-level claim also broadens the scope of applicability and protection, recognizing that the invention can function not only as a component but as part of a complete, intelligent magnetic sensing solution.

According to a further aspect, a method for sensing out-of-plane magnetic fields is provided. The method includes the steps of providing a layer stack that includes precisely one reference system and, adjacent to the reference system, a synthetic antiferromagnetic (SAF) free-layer. The SAF free-layer includes a first ferromagnetic signal layer and a second ferromagnetic balance layer. These two layers are antiferromagnetically coupled via a non-magnetic coupling layer and each possesses an easy-plane anisotropy. The method further includes applying an external out-of-plane magnetic field to the SAF free-layer and detecting a change in a magnetoresistance signal that corresponds to a variation in the out-of-plane magnetization of the SAF free-layer. This defines a method that describes how the sensor operates to detect magnetic fields in practice. The method begins by providing a specific physical configuration: a magnetic tunnel junction composed of a single reference system and a SAF free-layer made up of two ferromagnetic layers with easy-plane anisotropy, coupled via the RKKY mechanism. Once this structure is in place, the sensor is exposed to an external magnetic field oriented out of the plane of the layer stack. This field causes a controlled rotation or reorientation of the magnetization within the SAF free-layer. The key sensing mechanism is the detection of this magnetic reorientation through a change in the sensor's electrical resistance—specifically, a change in tunnel magnetoresistance (TMR) or giant magnetoresistance (GMR), depending on the implementation. The variation in resistance is then used to determine the strength of the out-of-plane magnetic field. The method may enable precise and robust detection of magnetic fields that are perpendicular to the surface of the sensor structure. By using a SAF free-layer with antiferromagnetic coupling and in-plane anisotropy, the method may minimize the impact of in-plane cross-fields, which commonly interfere with out-of-plane measurements. The resulting magnetoresistive signal is largely governed by the out-of-plane component of the external field, leading to a cleaner and more linear response. Furthermore, the use of a single reference system and a tightly coupled SAF structure may simplify the layer stack and reduce complexity, all while preserving directional sensitivity and high signal integrity. The method may be implemented in a variety of sensor platforms—such as discrete devices or integrated systems—and may serve applications requiring reliable, high-resolution magnetic field measurements in environments subject to magnetic noise or mechanical constraints.

According to yet a further aspect, a magnetoresistive sensor for in-plane magnetic field sensing is provided. The sensor includes a layer stack that includes a reference system with an in-plane magnetization, and a SAF free-layer disposed adjacent to the reference system. The SAF free-layer includes a first ferromagnetic layer having an out-of-plane magnetic anisotropy, a second ferromagnetic layer also having an out-of-plane magnetic anisotropy, and a non-magnetic coupling layer interposed between the first and second ferromagnetic layers. The non-magnetic coupling layer is configured to couple the first and second ferromagnetic layers antiferromagnetically via a RKKY interaction.

This introduces a mirror architecture to that of the first aspect. Instead of being optimized to detect magnetic fields perpendicular to the layer plane (out-of-plane fields), this sensor is designed to sense in-plane magnetic fields. The reference system in this configuration has a fixed magnetization direction that lies within the plane of the sensor. In contrast, the SAF free-layer—whose magnetic state changes in response to the target field—includes ferromagnetic layers with an out-of-plane magnetic anisotropy, meaning that their preferred magnetization direction in the absence of external stimuli is perpendicular to the plane. These two ferromagnetic layers are separated by a non-magnetic spacer that enables antiferromagnetic RKKY coupling, maintaining antiparallel alignment of their magnetizations under zero field conditions. This configuration allows the SAF free-layer to begin in a near-zero net magnetic state but to respond in a controlled, linear way when an external in-plane field is applied—causing magnetization tilting and thereby resistance modulation, which is the basis for sensing.

This sensor architecture may offer robust and highly linear sensing of in-plane magnetic fields, while maintaining low sensitivity to unwanted out-of-plane interference. The out-of-plane magnetic anisotropy in the SAF free-layer may stabilize the initial antiparallel configuration of the SAF, keeping the net magnetization close to zero in the absence of a signal field. This may reduce magnetic noise, thermal drift, and residual bias. Upon application of an in-plane field, the magnetization of the SAF layers may tilt coherently away from their equilibrium orientation, producing a measurable change in magnetoresistance. Using RKKY-coupled out-of-plane layers for in-plane field sensing may also increase the stability and operational range of the sensor, since the SAF structure may withstand stronger parasitic field components without transitioning into a saturated or nonlinear regime.

Thus, the present disclosure provides magnetoresistive sensors for magnetic field sensing. A sensor includes a layer stack including a reference system with a fixed magnetization and a SAF free-layer disposed adjacent to the reference system. The SAF free-layer includes a first ferromagnetic layer and a second ferromagnetic layer, each having a magnetic anisotropy oriented orthogonally to the magnetization direction of the reference system, and a non-magnetic coupling layer interposed between the first and second ferromagnetic layers. The coupling layer is configured to couple the ferromagnetic layers antiferromagnetically via a Ruderman-Kittel-Kasuya-Yosida (RKKY) interaction. Depending on the configuration, the sensor is sensitive to either out-of-plane or in-plane magnetic field components while exhibiting low cross-field sensitivity. The SAF structure enables low-noise operation with a near-zero net magnetization under zero field, supporting high linearity and directional robustness.

### BRIEF DESCRIPTION OF THE FIGURES

Some examples of apparatuses and/or methods will be described in the following by way of example only, and with reference to the accompanying figures, in which

FIG. 1 shows a schematic cross-sectional view of a magnetoresistive sensor for out-of-plane magnetic field sensing, including a SAF free-layer and a reference system with perpendicular magnetization;

FIG. 2 shows an exploded and enlarged view of the layer stack of the sensor of FIG. 1, illustrating example material stacks for the SAF free-layer, the reference layer, and the hard-magnetic pinning structure;

FIG. 3 shows a sensor arrangement comprising a Wheatstone bridge with four magnetoresistive resistors, each implemented with a SAF-based sensor, including reference magnetization directions and optional soft magnetic shielding elements, it further illustrates the layout of the sensors on a substrate and an embodiment of parallel soft magnetic shielding structures, and

FIG. 4 shows a schematic cross-sectional view of a magnetoresistive sensor for in-plane magnetic field sensing, including a SAF free-layer and a reference system with in-plane magnetization.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

In order to realize a linear and robust out-of-plane (OOP) magnetic field sensor based on the GMR or TMR effect, a sensing layer with minimal susceptibility to in-plane (IP) magnetic disturbances is required. Conventional approaches using ferromagnetic sensing layers with in-plane easy axes often exhibit significant cross-field sensitivity, as their magnetization responds not only to the desired OOP field component but also to IP field components. This leads to superimposed effects and reduced measurement precision. Although vortex-based sensing layers can partially suppress this cross-sensitivity due to their localized core dynamics, they become unstable under elevated IP fields and tend to revert to a homogeneous state with restored sensitivity to cross-fields.

An alternative solution, which maintains high linearity and robustness under in-plane magnetic interference, involves the use of a synthetic antiferromagnetic (SAF) free-layer comprising two in-plane magnetized ferromagnetic layers that are antiferromagnetically coupled. This configuration enables near-complete flux closure in the absence of external fields and significantly reduces the net magnetization of the sensing layer. As a result, the SAF structure responds primarily to the OOP field component, while exhibiting minimal response to in-plane fields, thus achieving the desired cross-field immunity.

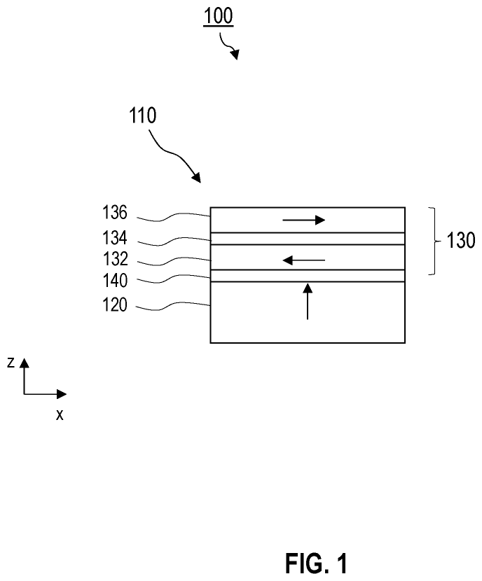

FIG. 1 schematically illustrates an example of such a magnetoresistive sensor 100 for sensing magnetic fields oriented perpendicular to the plane of a magnetic layer stack, also referred to as out-of-plane magnetic field sensing.

The sensor 100 includes a layer stack 110 comprising a reference system 120 and a synthetic antiferromagnetic (SAF) free-layer 130, which is disposed adjacent to the reference system 120. The SAF free-layer 130 contains two ferromagnetic layers 132 and 136, separated by a non-magnetic coupling layer 134. These layers are configured such that the magnetizations of the ferromagnetic layers 132 and 136 lie in the (x-y) plane and are aligned antiparallel to each other, while the reference system 120 provides a magnetization that is directed out of the plane (z-direction).

The sensor 100 is constructed as a vertically layered structure, with the layer stack 110 forming an active sensing element. The arrangement and magnetic orientations of the constituent layers are configured to enable the detection of out-of-plane magnetic field components (z-components) with minimal influence from in-plane magnetic interference.

The layer stack 110 comprises two primary components: the reference system 120 and the SAF free-layer 130. In the illustrated embodiment, the reference system 120 is located beneath the free-layer 130 and exhibits a fixed magnetization oriented out-of-plane, as indicated by the upward-pointing arrow. In various embodiments, the reference system 120 may be implemented using a perpendicularly magnetized multilayer stack, such as a Co/Pt, Co/Ni, or FePt-based synthetic antiferromagnet, or using a single ferromagnetic layer with high perpendicular anisotropy. The magnetization of the reference system 120 may be stabilized by exchange bias, pinning layers, or interfacial anisotropy, ensuring that it remains insensitive to external field variations during operation.

In the illustrated embodiment, the SAF free-layer 130 is arranged above the reference system 120 and includes a first ferromagnetic layer 132 and a second ferromagnetic layer 136. Both of these layers exhibit easy-plane anisotropy, meaning their magnetic moments preferentially lie within the (x-y) plane of the layer. The order can be also reversed. In the absence of an external magnetic field, their magnetizations align antiparallel to one another, as indicated by the opposing horizontal arrows. The materials used for these layers may include CoFeB, NiFe, or other soft magnetic alloys, and the thicknesses may be tailored to balance the magnetic moments and optimize the antiferromagnetic coupling strength.

Between the ferromagnetic layers 132 and 136 lies a non-magnetic coupling layer 134. This layer is configured to facilitate antiferromagnetic coupling via the RKKY interaction. The coupling layer 134 may be a metallic layer, e.g., composed of ruthenium, iridium, or other suitable elements known to support strong RKKY coupling when deposited at sub-nanometer thicknesses. This coupling may ensure that the magnetizations of the first and second ferromagnetic layers 132 and 136 remain antiparallel over a wide range of external field conditions.

The overall magnetization of the SAF free-layer 130 is close to zero in the absence of an external field, due to the cancellation of the opposing in-plane magnetizations of layers 132 and 136. When an external out-of-plane field is applied, it induces a differential tilt or canting in the magnetizations, altering the net moment along the direction of the reference magnetization in layer 120. This variation results in a measurable change in the resistance of the magnetic tunnel junction (or other magnetoresistive configuration), which forms the basis of the sensing mechanism.

Layer 140, as illustrated in FIG. 1, is arranged between the synthetic antiferromagnetic (SAF) free-layer 130 and the reference system 120, and forms a functional interface between these two magnetic structures within the layer stack 110 of the magnetoresistive sensor 100. Depending on the specific embodiment, layer 140 may serve different roles:

In one embodiment, layer 140 is a tunnel barrier. The tunnel barrier 140 is electrically insulating and configured to allow spin-dependent electron tunneling between the SAF free-layer 130 and the reference system 120. In this configuration, the magnetoresistive sensor 100 operates based on the tunneling magnetoresistance (TMR) effect. The resistance of the sensor varies as a function of the relative magnetization orientations of the SAF free-layer 130 and the reference system 120.

The tunnel barrier 140 is specifically positioned between the first ferromagnetic layer 132 of the SAF free-layer 130 and the reference system 120. This means that the magnetic moment of the first ferromagnetic layer 132 directly influences the tunnel current across the barrier, and thereby the sensor signal. Materials commonly used for such a tunnel barrier include magnesium oxide (MgO), aluminum oxide (Al₂O₃), or similar high-resistance insulators with good spin filtering characteristics. The tunnel barrier may have a thickness in the range of 1-2 nanometers, optimized to balance tunneling probability and magnetoresistive contrast.

In another embodiment, layer 140 may instead be a conductive spacer layer. In this configuration, the sensor operates based on the giant magnetoresistance (GMR) effect, in which electron transport occurs through a conductive medium, and the resistance depends on spin-dependent scattering. When implemented as a conductive spacer, the material of layer 140 may be chosen from non-magnetic metals such as copper (Cu), silver (Ag), or chromium (Cr), typically with a thickness of a few nanometers to ensure efficient current transport and spin coherence.

This GMR-type embodiment may be selected where lower resistance or improved thermal stability is desired, or where process integration with existing semiconductor technology favors the use of metallic spacers over tunnel barriers.

In the magnetoresistive sensor 100 shown in FIG. 1, the first ferromagnetic layer 132 of the SAF free-layer 130 may act as a signal layer, while the second ferromagnetic layer 136 may function as a balancing layer.

The first ferromagnetic layer 132 is positioned adjacent to the tunnel barrier 140 (or alternatively, the conductive spacer layer), which separates it from the reference system 120. Because of this placement, it is the magnetization of layer 132 that directly interacts with the reference magnetization across the interface. In a TMR implementation, this interaction governs the tunneling probability of spin-polarized electrons; in a GMR structure, it determines the degree of spin-dependent scattering. In both cases, changes in the magnetization direction of layer 132 in response to an external magnetic field produce a measurable change in electrical resistance.

Consequently, the first ferromagnetic layer 132 serves as the signal-generating layer. It is the part of the free-layer system 130 whose magnetic state is actively modulated by the sensed field (typically an out-of-plane component), and whose alignment relative to the reference system 120 controls the output signal of the sensor 100. The magnetic response of this layer may therefore be designed to be highly sensitive, linear, and reproducible within the desired sensing range.

The second ferromagnetic layer 136 is located on the opposite side of the non-magnetic coupling layer 134, farther away from the reference system 120. While it may carry current together with the rest of the free-layer, its magnetization does not couple directly to the tunnel barrier and therefore does not contribute to the magnetoresistive signal; instead it serves primarily to magnetically balance the first ferromagnetic layer 132 via antiparallel RKKY coupling.

The balancing layer 136 serves multiple purposes: It may minimize the net magnetic moment of the SAF free-layer 130 in the absence of an external field, thereby reducing magnetic noise and bias. It may increase the magnetic stiffness of the system, improving the stability of the antiparallel configuration. It may allow the SAF structure to maintain its initial state against parasitic in-plane fields, thereby reducing cross-field sensitivity and enhancing robustness.

Because layer 136 is magnetically active but does not contribute directly to the sensor output, it can be optimized independently—for example, by adjusting its thickness, anisotropy, or saturation magnetization—to ensure effective compensation without affecting the signal characteristics of layer 132.

A clear division of roles between the signal layer 132 and the balancing layer 136 is fundamental to the functioning of a SAF-based magnetoresistive sensor. It allows the sensor to retain: Sensitivity to out-of-plane magnetic fields, due to the direct modulation of the signal layer 132 near the tunnel barrier 140. Low sensitivity to in-plane cross-fields, due to the symmetrical and antiparallel configuration of the SAF. Excellent linearity and reproducibility, since only one layer contributes to the signal while the other provides passive stabilization. This architecture may combine the benefits of low magnetic noise, high directionality, and a predictable, quasi-linear rotation of the free-layer magnetization, making it suitable for applications that require precise and robust out-of-plane field detection.

The SAF free-layer 130 shown in FIG. 1 is a system comprising, in its simplest form, two ferromagnetic layers 132 and 136 separated by a non-magnetic spacer layer 134. The two ferromagnetic layers are antiferromagnetically coupled to one another via the RKKY-interaction. This interaction represents a form of indirect exchange coupling, mediated through conduction electrons in a very thin metallic spacer, typically a few ångströms thick. Suitable materials for the coupling layer 134 include, for example, ruthenium, iridium, or other metals known to support antiferromagnetic coupling over atomic-scale distances.

In this configuration, the magnetic behavior of the free-layer 130 is governed not only by the externally applied magnetic field but also by the internal exchange forces resulting from RKKY coupling, as well as the shape anisotropy of the individual ferromagnetic layers. The first ferromagnetic layer 132, being adjacent to the tunnel barrier 140, acts as the signal layer. Its magnetization direction determines the tunneling resistance relative to the fixed out-of-plane magnetization of the reference system 120. The second ferromagnetic layer 136 serves as the balancing layer. Its magnetization is antiparallel to that of the signal layer due to the antiferromagnetic RKKY interaction. The combination of these two layers in an antiparallel configuration creates a net magnetic moment that is close to zero in the absence of an external field, thereby suppressing magnetic noise and parasitic self-fields.

For the SAF structure to function effectively in out-of-plane field sensing, specific requirements may be met. The signal layer 132 may be formed from a material composition and thickness suitable to support a strong TMR effect. Moreover, the combination of signal layer 132 and balance layer 136 should exhibit sufficient sensitivity to out-of-plane fields while maintaining a linear response within the relevant field range. To suppress undesired response to in-plane cross-fields, the anisotropy and saturation magnetization of the two layers should be matched or deliberately offset to create a well-compensated system.

When an external in-plane magnetic field is applied, the magnetizations of both ferromagnetic layers 132, 136 experience a torque that tends to align them with the field direction. However, the antiferromagnetic RKKY coupling counteracts this tendency, maintaining the antiparallel alignment. The result is a dynamic equilibrium in which the magnetizations of layers 132 and 136 tilt only slightly toward the field direction while remaining largely antiparallel. The strength of the internal RKKY coupling determines how much external field is required to overcome this equilibrium. Depending on the material parameters, this may lead to a magnetization response that is highly stable against in-plane perturbations. In some cases, the energy minimum of the system favors uniformly antiparallel magnetizations; in others, it may result in the formation of antiferromagnetic domain structures.

In the case of out-of-plane magnetic fields, the magnetization of the SAF free-layer 130 behaves similarly to a single ferromagnet with easy-plane anisotropy. The RKKY interaction contributes an effective anisotropy term that resists out-of-plane alignment. As the strength of the applied out-of-plane field increases, the magnetization vectors of the two ferromagnetic layers 132, 136 begin to gradually tilt out of the plane. This transition does not occur abruptly but proceeds continuously as a function of field strength. The effective anisotropy field that must be overcome to achieve saturation of the SAF can be described as the sum of the intrinsic anisotropy field Hₖ and twice the RKKY coupling field HRKKY. The resulting out-of-plane component of the net magnetization, Mz, as a function of the applied field Hz can be described analytically by:

Mz≈−Hz2KeffJs+2JRKKY/tJs

where Js denotes the saturation polarization of the ferromagnetic material, t the layer thickness, and JRKKY the strength of the antiferromagnetic exchange coupling. For thin-film geometries with interface-or bulk-driven perpendicular anisotropy K₁, the effective anisotropy Keff can be approximated as:

Keff≈K1−Js22μ0.

In certain embodiments, Keff may take on negative values, indicating that the system has easy-plane anisotropy. This means that, in the absence of an external field, the magnetization vectors remain confined to the plane of the layers and have no vertical (z-direction) component. The negative value of JRKKY ensures antiparallel coupling between the two layers. Under these conditions, and when the magnetic properties are well-balanced, the relationship between Mz and Hz becomes nearly linear, which is desirable for precision sensing applications.

A conventional ferromagnetic sensing layer responds to an external field by tilting its magnetization toward the field direction to minimize its Zeeman energy. In contrast, the SAF free-layer 130, due to its antiferromagnetic coupling, can partially or fully resist this tilt, depending on the material design. By carefully selecting the saturation magnetization, anisotropy, and thickness of the constituent layers, a SAF free-layer can be engineered to show minimal sensitivity to in-plane magnetic fields while remaining responsive to out-of-plane components. This behavior is confirmed through example simulation data, which show that up to approximately 500 mT of in-plane field has little to no effect on the out-of-plane response. Only near the exchange field threshold—typically around 550 mT—does the in-plane field begin to significantly disturb the magnetization alignment.

Experimental measurements and micromagnetic simulations both indicate that the out-of-plane magnetization component Mz remains essentially constant over a broad range of superimposed in-plane fields. Although the signal layer 132 and the balance layer 136 display slightly different individual hysteresis loops, their antiparallel coupling may keep the net SAF magnetization highly stable: the variation of Mz stays below about 1% of its saturation value across the entire intended operating window. These results demonstrate the strong immunity of the free-layer to parasitic in-plane excitation and confirm the wide cross-field-robust range of the sensor.

The SAF free-layer architecture described above may provide a robust platform for out-of-plane magnetic field sensing, with inherently low sensitivity to parasitic in-plane fields. The ability to achieve high RKKY coupling strengths—up to 1 T in some material systems—allows the SAF to maintain performance even in stray field environments exceeding 100 mT. Moreover, the total thickness of the SAF free-layer 130 can be maintained in the range of a few nanometers (e.g., <10 nm), making it significantly more compact and cost-effective than vortex-based alternatives, which typically require thicker structures to achieve similar field robustness. Importantly, the sensing behavior of the SAF is independent of lateral dimensions, meaning that sub-micrometer feature sizes are not required to maintain sensor performance. This enables straightforward integration into semiconductor processes and supports high-yield, scalable sensor manufacturing.

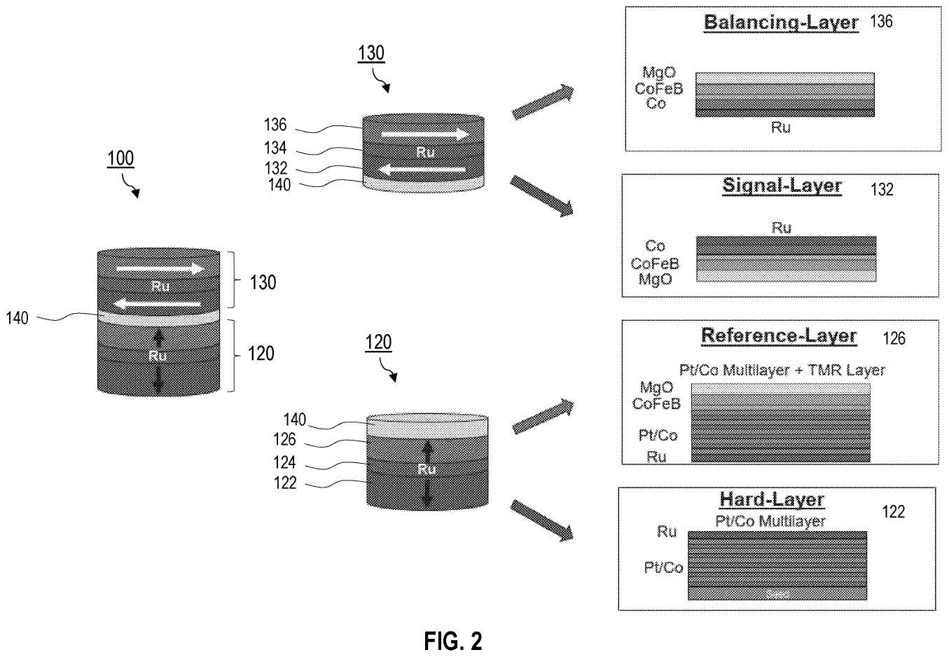

FIG. 2 shows an exploded and schematic illustration of the magnetoresistive sensor 100 in accordance with an embodiment of the present disclosure. The figure provides a functional decomposition of the layer stack 110, with focus on the structure and material composition of the SAF free-layer 130, the reference system 120, and the individual magnetic subcomponents including signal layer 132, balance layer 136, and tunnel barrier 140. Additionally, FIG. 2 highlights example layer material stacks associated with these subcomponents, including a hard-magnetic pinning system.

The SAF free-layer 130 comprises the signal layer 132 and the balancing layer 136, which are antiferromagnetically coupled across a thin non-magnetic coupling layer 134, shown here formed from ruthenium (Ru). The coupling layer 134 is designed to mediate an RKKY interaction between the ferromagnetic layers 132 and 136. The magnetic moments of the two ferromagnetic layers 132, 136 are aligned antiparallel, as schematically indicated by the opposing arrows, thus forming a compensated SAF structure. The SAF free-layer 130 is magnetically responsive and configured to react to external out-of-plane fields by varying the relative alignment of its constituent magnetizations, thereby modulating the magnetoresistance of the sensor.

The signal layer 132 is the ferromagnetic layer positioned adjacent to the tunnel barrier 140. In this configuration, it acts as the active layer in the TMR stack. In one or more embodiments, the signal layer 132 comprises a thin film structure including one or more of Co, CoFeB, and MgO, optionally with anisotropy-enhancing multilayers such as Pt/Co, Pd/Co, or Co/Ni. The total thickness of the magnetic stack of the signal layer 132 may be in the range of 1-5 nanometers, a range that may maximize the TMR ratio while allowing a designer to adjust—if needed—the effective anisotropy and saturation moment of the layer. As indicated in the magnified structure, the signal layer 132 comprises a multilayer stack including, from bottom to top, an MgO layer (tunnel barrier 140), a CoFeB alloy layer, and a Co layer, capped by a Ru layer (coupling layer 134). The magnetic and structural configuration of the signal layer 132 is selected to provide strong spin polarization, perpendicular anisotropy, and efficient TMR performance when placed adjacent to the tunnel barrier 140.

The balance layer 136, positioned above the signal layer 132 and coupling layer 134, serves to magnetically counteract the signal layer 132. Because it is not in direct contact with the tunnel barrier 140, the balancing layer 136 may offer greater flexibility in terms of thickness and material composition. It may comprise multilayers of Co, CoFeB, MgO, or other ferromagnetic materials, and may be further capped or seeded to tune its magnetic moment, anisotropy, and dynamic behavior. The balancing layer 136 is shown in the magnified structure and, in one embodiment, comprises a multilayer stack formed on top of a ruthenium (Ru) coupling layer 134. The magnetic stack includes a ferromagnetic Co layer, a CoFeB alloy layer, and a capping layer of MgO. The Co and CoFeB layers are configured to provide the required magnetic moment and anisotropy properties for compensating the signal layer 132, while the MgO layer may serve as a capping or diffusion barrier. The Ru layer 134 enables antiferromagnetic RKKY coupling to the adjacent signal layer 132 through the coupling layer 134. In this configuration, the balancing layer 136 is magnetically active but electrically decoupled from the tunnel barrier 140.

In some embodiments, the balancing layer 136 may be fabricated with a layer stack that is substantially similar to—or even nominally identical to—the stack used for the signal layer 132. Adopting the same material sequence (for example a CoFeB/Co interface layer at the MgO side, optional Pt/Co or Co/Ni anisotropy-assist multilayers, and comparable total thickness) may simplify deposition and patterning because both ferromagnetic layers can be grown in a single run with identical sputter targets and process conditions. Using matching stacks may also promote accurate magnetic compensation: if the two layers possess nearly equal saturation moment and anisotropy, the antiferromagnetic RKKY coupling through the spacer 134 may enforce a robust antiparallel configuration with a net in-plane moment close to zero, thereby maximizing cross-field immunity without the need for extensive individual tuning of layer thickness or composition.

Between the SAF free-layer 130 and the reference system 120, a tunnel barrier 140 is arranged. The tunnel barrier 140 typically comprises MgO or Al₂O₃ and serves to electrically separate the SAF from the reference while allowing spin-polarized tunneling. Its thickness may be in the range of 1-2 nm and its quality determines the TMR ratio and spin filtering efficiency. In some embodiments, layer 140 may instead be a conductive spacer layer, as would be applicable in a GMR configuration.

The reference system 120 comprises a multilayer stack that includes a hard-magnetic pinning structure 122, a reference layer 126 with perpendicular magnetic anisotropy, and an MgO tunnel barrier 140 disposed on top of the reference layer 126. These elements are vertically arranged in the order: hard layer 122, coupling layer 124, reference layer 126, and tunnel barrier 140.

The hard layer 122 may be a SAF structure configured to stabilize the magnetic orientation of the reference layer 126. As shown in the magnified structure, the hard layer 122 may comprise a multilayer stack of alternating Pt and Co layers, designed to generate strong perpendicular magnetic anisotropy (PMA). To strengthen the pinning, an antiferromagnetic exchange-bias layer—such as PtMn, IrMn, MnN or MnNb—can be added either below the SAF stack (between seed and SAF) or above it (between SAF and the Ru spacer 124). The antiferromagnet may establish a robust out-of-plane exchange bias, further preventing spontaneous reversal of the hard layer. The stack may be formed on top of a seed layer, which may promote the required crystalline texture and interface quality. The stack may be terminated by a ruthenium (Ru) spacer, which serves as the coupling layer 124 and mediates RKKY antiferromagnetic coupling to the overlying reference layer 126. The magnetization direction of the hard layer 122 is oriented in the out-of-plane direction, as indicated by the downward-pointing arrow.

The reference layer 126 is disposed above the coupling layer (farther away from the film substrate) 124 and forms the magnetically fixed element of the magnetoresistive sensor, against which the free-layer's 130 magnetization is compared. In other embodiments the reference layer 126 is disposed below the coupling layer (closer to the film substrate)

As depicted in the magnified structure, the layer stack includes, from bottom to top, a Ru interface layer, a Pt/Co multilayer to ensure strong PMA, a CoFeB layer that acts as a spin-polarized tunneling electrode, and a top MgO layer serving as the tunnel barrier 140. The Pt/Co multilayer may provide thermal stability and high coercivity, ensuring that the magnetization remains fixed under operational conditions. The CoFeB layer may ensure efficient spin polarization for tunneling electrons, and the MgO barrier enables the TMR effect by allowing spin-dependent tunneling to the adjacent signal layer.

The Ru coupling layer 124 may provide antiferromagnetic exchange interaction between the hard layer 122 and the reference layer 126, resulting in a synthetic antiferromagnetic configuration that minimizes net stray fields and may improve thermal robustness. The coupling strength and the relative thicknesses of the Pt/Co layers in 122 and 126 may be selected such that the magnetization of the reference layer 126 is pinned reliably, even in the presence of strong external magnetic fields or thermal disturbances.

The MgO tunnel barrier 140 is disposed on top of the reference layer 126 and interfaces with the signal layer 132 of the SAF free-layer. In other embodiments the reference layer is disposed on top of the tunnel barrier. The MgO layer enables tunneling magnetoresistance (TMR) by filtering electrons based on their spin orientation and forming the basis of the resistance modulation mechanism in the sensor.

In this configuration, the reference system 120 as a whole may form a highly stable and directionally selective magnetic structure, enabling accurate sensing of out-of-plane magnetic fields while providing excellent thermal and magnetic stability due to the SAF-based pinning and PMA characteristics of the constituent layers.

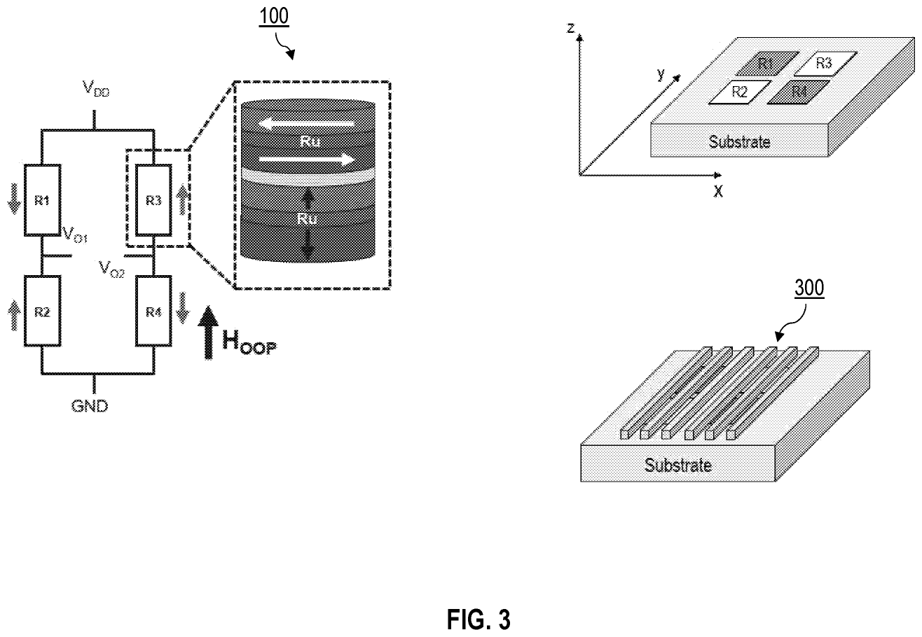

FIG. 3 illustrates different aspects of a sensor arrangement comprising a Wheatstone bridge configuration with magnetoresistive sensing elements 100, implemented using synthetic antiferromagnetic layer stacks. The figure also shows the integration of the sensing elements on a common substrate and the use of soft magnetic shielding to improve cross-field immunity.

On the left side of FIG. 3, a Wheatstone bridge circuit is shown, comprising four resistors labeled R1 to R4. Each resistor R1-R4 may be implemented as a magnetoresistive sensor element 100 that includes a multilayer structure with a SAF free-layer 130 and a fixed reference layer system 120. The bridge is supplied with a voltage VDD and provides two output voltages VO1 and VO2 for differential sensing. The bridge is sensitive to magnetic fields applied in the out-of-plane direction, denoted by HOOP.

Each sensor element 100 within the bridge includes a reference system 120 with a fixed out-of-plane magnetization. As indicated by the arrows, the reference magnetizations differ between the individual resistors: resistors R1 and R4 have reference magnetizations pointing downward, while resistors R2 and R3 have reference magnetizations pointing upward. This opposing reference configuration allows for a differential response to an out-of-plane magnetic field HOOP. As the field is applied, the relative alignment between the signal layer 132 and the reference layer 120 in each sensor element 100 changes differently, depending on the direction of the reference magnetization. This design improves the symmetry and sensitivity of the Wheatstone bridge and enhances linearity and immunity to common-mode interference.

In the upper right portion of FIG. 3, the four magnetoresistive sensors R1 to R4 are shown integrated into a planar layout on a common substrate. The sensor elements 100 are placed in a two-by-two array, with each unit comprising a layer stack 110 as described previously. This illustrates a monolithic integration of the full bridge circuit into a single chip or die, which facilitates compact packaging and consistent field exposure across the sensing elements.

The lower right portion of FIG. 3 shows an embodiment further comprising soft magnetic shielding 300. The shielding 300 is arranged adjacent to the respective layer stacks 110 of the sensors R1-R4 and is configured to reduce the influence of an external magnetic field along a shielding axis on the respective free-layer 130 of each sensor. In the illustrated embodiment, the shielding 300 comprises a plurality of elongated shielding bars formed from a soft magnetic material. These bars are oriented parallel to one another and placed above or laterally adjacent to the sensors, such that they can redirect or attenuate unwanted magnetic field components that are not aligned with the sensing direction (e.g., in-plane parasitic fields).

The shielding 300 may be implemented in different configurations. In some embodiments, the soft magnetic shielding is formed from high-permeability materials such as NiFe or CoFe alloys and may consist of single or multiple parallel bars. The longitudinal axes of the shielding elements may extend parallel or perpendicular to the direction of the shielding axis, depending on the dominant direction of the expected cross-field interference. In some variants, the shielding bars may be arranged in a crossed configuration, with first and second sets of bars intersecting at right angles to provide bidirectional shielding in both x- and y-directions.

The placement of the shielding 300 may also vary. In certain embodiments, the shielding is disposed laterally next to the layer stacks 110. In other embodiments, the shielding is arranged vertically above or below the sensor elements, for example embedded within the package or deposited in a subsequent metallization layer. The shielding bars may have an elongated or cuboidal geometry, with an extension perpendicular to the shielding axis that is greater than parallel to it, thereby maximizing flux guidance and shielding effectiveness.

In this configuration, the shielding 300 acts to reduce the effective parasitic magnetic flux reaching the sensitive regions of the free-layer 130, while preserving the field sensitivity in the desired out-of-plane direction. This improves the cross-field robustness of the bridge circuit and ensures more accurate and stable sensor output under disturbed or noisy magnetic environments.

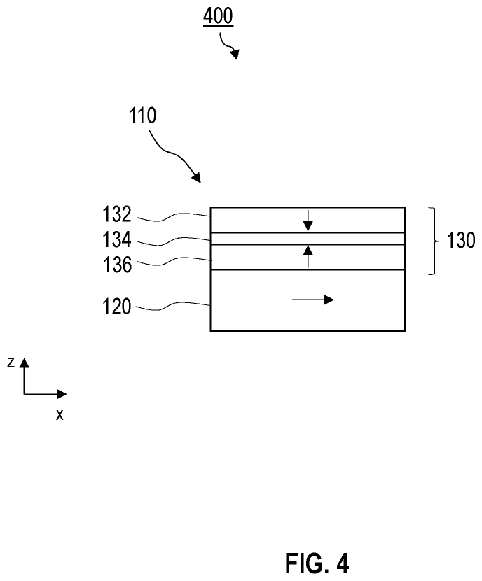

FIG. 4 schematically illustrates an example of a magnetoresistive sensor 400 that is configured for sensing magnetic fields oriented within the plane of a magnetic layer stack (in-plane magnetic field sensing), as opposed to the out-of-plane sensing structure shown in FIG. 1. The magnetoresistive sensor 400 comprises a layer stack 110, which includes a SAF free-layer 130 and a reference system 120 disposed adjacent to the SAF free-layer.

In contrast to the configuration illustrated in FIG. 1, the reference system 120 of FIG. 4 is characterized by an in-plane magnetization, as indicated by the rightward-pointing arrow. This directional alignment establishes the sensor's sensitivity axis within the plane of the layer stack, thereby enabling detection of magnetic field components parallel to the plane, e.g., along the x- or y-axis.

The SAF free-layer 130 comprises a first ferromagnetic layer 132, a second ferromagnetic layer 136, and a non-magnetic coupling layer 134 interposed therebetween. Both ferromagnetic layers 132 and 136 exhibit out-of-plane magnetic anisotropy, as indicated by the vertical arrows pointing in opposite directions. This means that, in the absence of external magnetic fields, the magnetization vectors of the layers 132 and 136 align antiparallel along the z-axis. The antiparallel configuration is stabilized by the non-magnetic coupling layer 134, which is configured to mediate antiferromagnetic coupling via the RKKY interaction.

Because of the out-of-plane anisotropy and antiferromagnetic coupling, the SAF free-layer 130 adopts a near-zero net magnetization in the quiescent state. However, when an external in-plane magnetic field is applied, the magnetization vectors of the ferromagnetic layers 132 and 136 are tilted away from their original perpendicular orientations toward the in-plane direction. This tilting occurs in a coupled, symmetric fashion due to the RKKY interaction, leading to a measurable modulation of resistance via the magnetoresistive effect—either TMR or GMR depending on the implementation. The net magnetization projection along the direction of the reference magnetization (in-plane) increases as a function of the applied field, thereby forming the basis of the sensing signal.

This architecture represents a mirror configuration relative to the out-of-plane sensing structure shown in FIG. 1. In the embodiment of FIG. 1, the SAF free-layer 130 has in-plane anisotropy and responded to out-of-plane fields, whereas in the embodiment of FIG. 4, the SAF free-layer has out-of-plane anisotropy and responds to in-plane fields. In both cases, the SAF structure ensures a high degree of magnetic stability and cross-field immunity, as only the desired component of the external magnetic field causes a deviation from the antiparallel baseline configuration.

The vertical magnetization states of layers 132 and 136 in FIG. 4, combined with the in-plane magnetization of reference system 120, result in a device that is selectively sensitive to lateral field components and robust against parasitic out-of-plane disturbances. This configuration may be particularly advantageous in applications where spatial or directional field resolution in the plane is required, and where high immunity to background field noise is essential.

The described structures, including the synthetic antiferromagnetic free-layers, reference systems, and optional shielding configurations, may be adapted to a wide range of magnetic field sensing applications, including but not limited to position detection, current sensing, and rotational encoding. The concepts presented herein support miniaturized, low-noise, and cross-field-robust sensor architectures that may be readily integrated into monolithic or system-level solutions. While particular materials and geometries have been disclosed, alternative implementations using equivalent materials or geometries are likewise encompassed by the disclosure.

The aspects and features described in relation to a particular one of the previous examples may also be combined with one or more of the further examples to replace an identical or similar feature of that further example or to additionally introduce the features into the further example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:

Aspect 1: A magnetoresistive sensor for out-of-plane magnetic field sensing, comprising: a layer stack with a reference system comprising an out-of-plane magnetization; and a synthetic antiferromagnetic (SAF) free-layer disposed adjacent to the reference system, the SAF free-layer comprising: a first ferromagnetic layer having an easy-plane anisotropy; a second ferromagnetic layer having an easy-plane anisotropy; and a non-magnetic coupling layer interposed between the first and second ferromagnetic layers and configured to couple the first and second ferromagnetic layers antiferromagnetically via a Ruderman-Kittel-Kasuya-Yosida (RKKY) interaction.

Aspect 2: The magnetoresistive sensor of Aspect 1, wherein the non-magnetic coupling layer is composed of ruthenium, iridium, tantalum, tungsten, or combinations thereof.

Aspect 3: The magnetoresistive sensor of any of Aspects 1-2, wherein the first ferromagnetic layer comprises a CoFeB/CoFe alloy.

Aspect 4: The magnetoresistive sensor of Aspect 3, wherein the first ferromagnetic layer comprises at least one additional element selected from the group consisting of Fe, Co, Pt, Pd, or Ni deposited on the CoFeB/CoFe alloy to modify a magnetocrystalline anisotropy and enable RKKY coupling.

Aspect 5: The magnetoresistive sensor of any of Aspects 1-4, further comprising: a tunnel barrier interposed between the SAF free-layer and the reference system.

Aspect 6: The magnetoresistive sensor of Aspect 5, wherein the tunnel barrier is interposed between the first ferromagnetic layer and the reference system.

Aspect 7: The magnetoresistive sensor of any of Aspects 1-6, further comprising: a conductive spacer layer interposed between the SAF free-layer and the reference system.

Aspect 8: The magnetoresistive sensor of any of Aspects 1-7, wherein the second ferromagnetic layer comprises a multilayer stack including one or more layers selected from the group of CoFe, CoNi, NiFe, CoB, CoFeB, or FeB, the multi-layer stack being configured to balance the magnetic moment of the first ferromagnetic layer.

Aspect 9: The magnetoresistive sensor of any of Aspects 1-8, wherein the SAF free-layer has a total thickness less than 10 nanometers.

Aspect 10: The magnetoresistive sensor of any of Aspects 1-9, wherein the first ferromagnetic layer has a thickness between 1 and 5 nanometers.

Aspect 11: The magnetoresistive sensor of any of Aspects 1-10, wherein the SAF free-layer is patterned into a circular or cylindrical geometry.

Aspect 12: The magnetoresistive sensor of Aspect 11, wherein the diameter of the SAF free-layer is less than one micrometer.

Aspect 13: The magnetoresistive sensor of any of Aspects 1-12, wherein the reference system comprises a stack exhibiting perpendicular magnetic anisotropy, the stack including one or more layers selected from the group of Co/Pt, Ni/Pt, Co/Ni, GdCo, CoCrPt, FePt, or a rare-earth-based alloy.

Aspect 14: The magnetoresistive sensor of any of Aspects 1-13, the layer stack includes precisely one reference system.

Aspect 15: The magnetoresistive sensor of any of Aspects 1-14, further comprising: a substrate, wherein the layer stack is disposed on the substrate, and the SAF free-layer is arranged between the substrate and the reference system.

Aspect 16: The magnetoresistive sensor of any of Aspects 1-15, further comprising: a substrate, wherein the layer stack is disposed on the substrate, and the reference system is arranged between the substrate and the SAF free-layer.

Aspect 17: The magnetoresistive sensor of any of Aspects 1-16, further comprising: at least one soft magnetic shielding arranged adjacent to the layer stack and configured to reduce an influence of an external magnetic field along a shielding axis on the SAF free-layer.

Aspect 18: The magnetoresistive sensor of Aspect 17, wherein the at least one soft magnetic shielding comprises a plurality of soft magnetic bars arranged in parallel, and wherein the plurality of soft magnetic bars each have a longitudinal axis extending perpendicularly or parallel to the shielding axis.

Aspect 19: A method for sensing out-of-plane magnetic fields, comprising: providing a layer stack comprising precisely one reference system, adjacent to the reference system, a synthetic antiferromagnetic (SAF) free-layer comprising a first ferromagnetic signal layer and a second ferromagnetic balance layer, the first ferromagnetic signal layer and the second ferromagnetic balance layer being antiferromagnetically coupled via a non-magnetic coupling layer and each having an easy-plane anisotropy; applying an external out-of-plane magnetic field to the SAF free-layer; and detecting a change in a magnetoresistance signal corresponding to a variation in an out-of-plane magnetization of the SAF free-layer.

Aspect 20: A magnetoresistive sensor for in-plane magnetic field sensing, comprising: a layer stack comprising a reference system having an in-plane magnetization; and a synthetic antiferromagnetic (SAF) free-layer disposed adjacent to the reference system, the SAF free-layer comprising: a first ferromagnetic layer having an out-of-plane magnetic anisotropy; a second ferromagnetic layer having an out-of-plane magnetic anisotropy; and a non-magnetic coupling layer interposed between the first ferromagnetic layer and the second ferromagnetic layer and configured to couple the first ferromagnetic layer and second ferromagnetic layer antiferromagnetically via a Ruderman-Kittel-Kasuya-Yosida (RKKY) interaction.

Aspect 21: A system configured to perform one or more operations recited in one or more of Aspects 1-20.

Aspect 22: An apparatus comprising means for performing one or more operations recited in one or more of Aspects 1-20.

1. A magnetoresistive sensor for out-of-plane magnetic field sensing, comprising:
a layer stack with a reference system comprising an out-of-plane magnetization; and
a synthetic antiferromagnetic (SAF) free-layer disposed adjacent to the reference system, the SAF free-layer comprising:
a first ferromagnetic layer having an easy-plane anisotropy;
a second ferromagnetic layer having an easy-plane anisotropy; and
a non-magnetic coupling layer interposed between the first and second ferromagnetic layers and configured to couple the first and second ferromagnetic layers antiferromagnetically via a Ruderman-Kittel-Kasuya-Yosida (RKKY) interaction.

2. The magnetoresistive sensor of claim 1, wherein the non-magnetic coupling layer is composed of ruthenium, iridium, tantalum, tungsten, or combinations thereof.

3. The magnetoresistive sensor of claim 1, wherein the first ferromagnetic layer comprises a CoFeB/CoFe alloy.

4. The magnetoresistive sensor of claim 3, wherein the first ferromagnetic layer comprises at least one additional element selected from the group consisting of Fe, Co, Pt, Pd, or Ni deposited on the CoFeB/CoFe alloy to modify a magnetocrystalline anisotropy and enable RKKY coupling.

5. The magnetoresistive sensor of claim 1, further comprising:
a tunnel barrier interposed between the SAF free-layer and the reference system.

6. The magnetoresistive sensor of claim 5, wherein the tunnel barrier is interposed between the first ferromagnetic layer and the reference system.

7. The magnetoresistive sensor of claim 1, further comprising:
a conductive spacer layer interposed between the SAF free-layer and the reference system.

8. The magnetoresistive sensor of claim 1, wherein the second ferromagnetic layer comprises a multilayer stack including one or more layers selected from the group of CoFe, CoNi, NiFe, CoB, CoFeB, or FeB, the multi-layer stack being configured to balance the magnetic moment of the first ferromagnetic layer.

9. The magnetoresistive sensor of claim 1, wherein the SAF free-layer has a total thickness less than 10 nanometers.

10. The magnetoresistive sensor of claim 1, wherein the first ferromagnetic layer has a thickness between 1 and 5 nanometers.

11. The magnetoresistive sensor of claim 1, wherein the SAF free-layer is patterned into a circular or cylindrical geometry.

12. The magnetoresistive sensor of claim 11, wherein the diameter of the SAF free-layer is less than one micrometer.

13. The magnetoresistive sensor of claim 1, wherein the reference system comprises a stack exhibiting perpendicular magnetic anisotropy, the stack including one or more layers selected from the group of Co/Pt, Ni/Pt, Co/Ni, GdCo, CoCrPt, FePt, or a rare-earth-based alloy.

14. The magnetoresistive sensor of claim 1, the layer stack includes precisely one reference system.

15. The magnetoresistive sensor of claim 1, further comprising:
a substrate, wherein the layer stack is disposed on the substrate, and the SAF free-layer is arranged between the substrate and the reference system.

16. The magnetoresistive sensor of claim 1, further comprising:
a substrate, wherein the layer stack is disposed on the substrate, and the reference system is arranged between the substrate and the SAF free-layer.

17. The magnetoresistive sensor of claim 1, further comprising:
at least one soft magnetic shielding arranged adjacent to the layer stack and configured to reduce an influence of an external magnetic field along a shielding axis on the SAF free-layer.

18. The magnetoresistive sensor of claim 17, wherein the at least one soft magnetic shielding comprises a plurality of soft magnetic bars arranged in parallel, and
wherein the plurality of soft magnetic bars each have a longitudinal axis extending perpendicularly or parallel to the shielding axis.

19. A method for sensing out-of-plane magnetic fields, comprising:
providing a layer stack comprising precisely one reference system, adjacent to the reference system, a synthetic antiferromagnetic (SAF) free-layer comprising a first ferromagnetic signal layer and a second ferromagnetic balance layer, the first ferromagnetic signal layer and the second ferromagnetic balance layer being antiferromagnetically coupled via a non-magnetic coupling layer and each having an easy-plane anisotropy;
applying an external out-of-plane magnetic field to the SAF free-layer; and
detecting a change in a magnetoresistance signal corresponding to a variation in an out-of-plane magnetization of the SAF free-layer.

20. A magnetoresistive sensor for in-plane magnetic field sensing, comprising:
a layer stack comprising a reference system having an in-plane magnetization; and
a synthetic antiferromagnetic (SAF) free-layer disposed adjacent to the reference system, the SAF free-layer comprising:
a first ferromagnetic layer having an out-of-plane magnetic anisotropy;
a second ferromagnetic layer having an out-of-plane magnetic anisotropy; and
a non-magnetic coupling layer interposed between the first ferromagnetic layer and the second ferromagnetic layer and configured to couple the first ferromagnetic layer and second ferromagnetic layer antiferromagnetically via a Ruderman-Kittel-Kasuya-Yosida (RKKY) interaction.
